(19) United States
(12) Patent Application Publication
(10) Pub. No.: US 2008/0057678 A1
(43) Pub. Date: Mar. 6, 2008

(54) Semiconductor on glass insulator made using improved hydrogen reduction process

(76) Inventors: Kishor Purushottam Gadkaree, Big Flats, NY (US); Suzanne Marie Matthews, Horseheads, NY (US)

Correspondence Address: CORNING INCORPORATED, SP-TI-3-1, CORNING, NY, 14831, US

(21) Appl. No.: 11/529,652

(22) Filed: Sep. 28, 2006

Related U.S. Application Data
(60) Provisional application No. 60/841,457, filed on Aug. 31, 2006.

(51) Int. Cl. H01L 21/00

(52) U.S. Cl. 438/460

(57) ABSTRACT

Methods and apparatus for producing a semiconductor on glass (SiOG) structure include: subjecting an implantation surface of a donor semiconductor wafer to an ion implantation process to create an exfoliation layer of the donor semiconductor wafer; reducing a concentration of hydrogen at least at the implantation surface of the donor semiconductor wafer using ozonated water; bonding the implantation surface of the exfoliation layer to a glass substrate using electrolysis; and separating the exfoliation layer from the donor semiconductor wafer, thereby exposing at least one cleaved surface.

### BACKGROUND

The present invention relates to the manufacture of a semiconductor-on-Insulator (SOI) structure using an improved pre-exfoliation and post-thinning cleaning film process.

To date, the semiconductor material most commonly used in semiconductor-on-insulator structures has been silicon. Such structures have been referred to in the literature as silicon-on-insulator structures and the abbreviation “SOI” has been applied to such structures. SOI technology is becoming increasingly important for high performance thin film transistors, solar cells, and displays, such as, active matrix displays. SOI structures may include a thin layer of substantially single crystal silicon (generally 0.1-0.3 microns in thickness but, in some cases, as thick as 5 microns) on an insulating material.

For ease of presentation, the following discussion will at times be in terms of SOI structures. The references to this particular type of SOI structure are made to facilitate the explanation of the invention and are not intended to, and should not be interpreted as, limiting the invention's scope in any way. The SOI abbreviation is used herein to refer to semiconductor-on-insulator structures in general, including, but not limited to, silicon-on-insulator structures. Similarly, the SiOG abbreviation is used to refer to semiconductor-on-glass structures in general, including, but not limited to, silicon-on-glass structures. The SiOG nomenclature is also intended to include semiconductor-on-glass-ceramic structures, including, but not limited to, silicon-on-glass-ceramic structures. The abbreviation SOI encompasses SiOG structures.

Various ways of obtaining SOI structures wafer include epitaxial growth of silicon (Si) on lattice matched substrates. An alternative process includes the bonding of a single crystal silicon wafer to another silicon wafer on which an oxide layer of SiO₂ has been grown, followed by polishing or etching of the top wafer down to, for example, a 0.05 to 0.3 micron layer of single crystal silicon. Further methods include ion-implantation methods in which either hydrogen or oxygen ions are implanted either to form a buried oxide layer in the silicon wafer topped by Si in the case of oxygen ion implantation or to separate (exfoliate) a thin Si layer to bond to another Si wafer with an oxide layer as in the case of hydrogen ion implantation.

The former two methods have not resulted in satisfactory structures in terms of cost and/or bond strength and durability. The latter method involving hydrogen ion implantation has received some attention and has been considered advantageous over the former methods because the implantation energies required are less than 50% of that of oxygen ion implants and the dosage required is two orders of magnitude lower.

U.S. Pat. No. 5,374,564 discloses a process to obtain a single crystal silicon film on a substrate using a thermal process. A silicon wafer having a planar face is subject to the following steps: (i) implantation by bombardment of a face of the silicon wafer by means of ions creating a layer of gaseous micro-bubbles defining a lower region of the silicon wafer and an upper region constituting a thin silicon film; (ii) contacting the planar face of the silicon wafer with a rigid material layer (such as an insulating oxide material); and (iii) a third stage of heat treating the assembly of the silicon wafer and the insulating material at a temperature above that at which the ion bombardment was carried out. The third stage employs temperatures sufficient to bond the thin silicon film and the insulating material together, to create a pressure effect in the micro-bubbles, and to cause a separation between the thin silicon film and the remaining mass of the silicon wafer. (Due to the high temperature steps, this process does not work with lower cost glass or glass-ceramic substrates.)

U.S. Patent Application No.: 2004/0229444 discloses a process that produces an SiOG structure. The steps include: (i) exposing a silicon wafer surface to hydrogen ion implantation to create a bonding surface; (ii) subjecting the implantation surface to oxidation, such as in oxygen plasma; (iii) bringing the bonding surface of the wafer into contact with a glass substrate; (iv) applying pressure, temperature and voltage to the wafer and the glass substrate to facilitate bonding therebetween; and (v) cooling the structure to a common temperature to facilitate separation of the glass substrate and a thin layer of silicon from the silicon wafer.

Disadvantageously, the process of subjecting the implantation surface to oxidation, such as oxygen plasma, requires specialized equipment and a complex control of the atmosphere under which oxidation takes place. This results in relatively high costs, both in terms of time and money. The cost problem may be significantly exacerbated if high throughput applications are needed or large SOI structure sizes are desired.

### SUMMARY OF THE INVENTION

In accordance with one or more embodiments of the present invention, methods and apparatus of forming a semiconductor on glass structure, include: subjecting an implantation surface of a donor semiconductor wafer to an ion implantation process to create an exfoliation layer of the donor semiconductor wafer; and reducing a concentration of hydrogen at least at the implantation surface of the donor semiconductor wafer using ozonated water.

The step of reducing the concentration of hydrogen may include washing the implantation surface in a first solution and then rinsing the implantation surface in the ozonated water. The first solution may include at least one of ammonia, hydrogen peroxide, and water.

In accordance with one or more further embodiments of the present invention, the step of reducing the concentration of hydrogen may include washing the implantation surface in a first solution, then washing the implantation surface in a second solution, and then rinsing the implantation surface in the ozonated water. The second solution may include at least one of hydrofluoric acid, hydrochloric acid, and water.

The process may also include subjecting at least the implantation surface to agitation of at least one of the first solution, the second solution, and the ozonated water. The agitation may include at least one of stirring the solution, magnetic stirring of the solution, ultrasonic wave propagation within the solution, megasonic wave propagation within the solution, and spray application of the solution.

The methods and apparatus in accordance with one or more further embodiments may further include: bonding the implantation surface of the exfoliation layer to a glass substrate using electrolysis; and separating the exfoliation layer from the donor semiconductor wafer, thereby exposing at least one cleaved surface. The step of bonding may include: heating at least one of the glass substrate and the semiconductor wafer; bringing the glass substrate into direct or indirect contact with the semiconductor wafer through the exfoliation layer; and applying a voltage potential across the glass substrate and the semiconductor wafer to induce the bond.

The methods and apparatus may further include: subjecting the cleaved surface to thinning or polishing to produce a post processed surface; and subjecting the post processed surface to a cleaning process using ozonated water.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a block diagram illustrating the structure of an SiOG device in accordance with one or more embodiments of the present invention;

FIG. 2 is a flow diagram illustrating process steps that may be carried out to produce the SiOG structure of FIG. 1; and

FIG. 3 is a block diagram illustrating an intermediate structure in which hydrogen ion implantation is applied to a donor semiconductor wafer;

FIG. 4 is a block diagram illustrating a immersion bath system for reducing the hydrogen concentration at least at a surface of the intermediate structure of FIG. 3;

FIG. 4A is a block diagram illustrating a spin/spray tool system for reducing the hydrogen concentration at least at a surface of the intermediate structure of FIG. 3;

FIG. 5 is a block diagram illustrating a bonding process in which the treated intermediate structure of FIG. 3 may be anodically bonded to a glass or glass ceramic substrate;

FIG. 6 is a block diagram illustrating an intermediate structure formed by separating the glass substrate and an exfoliation layer from the intermediate structure of FIG. 3; and

FIG. 7 is a block diagram illustrating a surface treatment process used to produce the alternative SiOG structure of FIG. 1.

### DETAILED DESCRIPTION OF THE PRESENT INVENTION

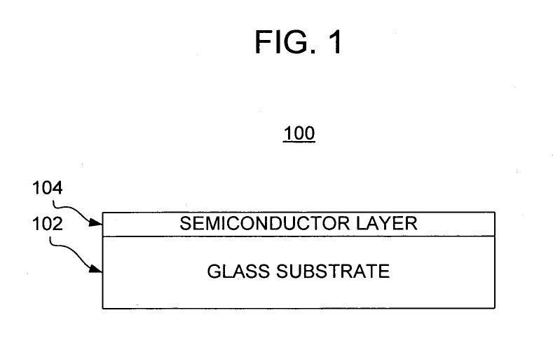

With reference to the drawings, wherein like numerals indicate like elements, there is shown in FIG. 1 an SiOG structure 100 in accordance with one or more embodiments of the present invention. The SiOG structure 100 may include a glass substrate 102, and a semiconductor layer 104. The SiOG structure 100 has suitable uses in connection with fabricating thin film transistors (TFTs), e.g., for display applications, including organic light-emitting diode (OLED) displays and liquid crystal displays (LCDs), integrated circuits, photovoltaic devices, etc.

The semiconductor material of the layer 104 may be in the form of a substantially single-crystal material. The term “substantially” is used in describing the layer 104 to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material.

For the purposes of discussion, it is assumed that the semiconductor layer 104 is formed from silicon. It is understood, however, that the semiconductor material may be a silicon-based semiconductor or any other type of semiconductor, such as, the III-V, II-IV, II-IV-V, etc. classes of semiconductors. Examples of these materials include: silicon (Si), germanium-doped silicon (SiGe), silicon carbide (SiC), germanium (Ge), gallium arsenide (GaAs), GaP, and InP.

The glass substrate 102 may be formed from an oxide glass or an oxide glass-ceramic. Although not required, the embodiments described herein may include an oxide glass or glass-ceramic exhibiting a strain point of less than about 1,000 degrees C. As is conventional in the glass making art, the strain point is the temperature at which the glass or glass-ceramic has a viscosity of 10^{14.6} poise (10^{13.6} Pa·s). As between oxide glasses and oxide glass-ceramics, the glasses may have the advantage of being simpler to manufacture, thus making them more widely available and less expensive.

By way of example, the glass substrate 102 may be formed from glass substrates containing alkaline-earth ions, such as, substrates made of CORNING INCORPORATED GLASS COMPOSITION NO. 1737 or CORNING INCORPORATED GLASS COMPOSITION NO. EAGLE 2000™ These glass materials have particular use in, for example, the production of liquid crystal displays.

The glass substrate may have a thickness in the range of about 0.1 mm to about 10 mm, such as in the range of about 0.5 mm to about 3 mm. For some SOI structures, insulating layers having a thickness greater than or equal to about 1 micron are desirable, e.g., to avoid parasitic capacitive effects which arise when standard SOI structures having a silicon/silicon dioxide/silicon configuration are operated at high frequencies. In the past, such thicknesses have been difficult to achieve. In accordance with the present invention, an SOI structure having an insulating layer thicker than about 1 micron is readily achieved by simply using a glass substrate 102 having a thickness that is greater than or equal to about 1 micron. A lower limit on the thickness of the glass substrate 102 may be about 1 micron.

In general, the glass substrate 102 should be thick enough to support the semiconductor layer 104 through the bonding process steps, as well as subsequent processing performed on the SiOG structure 100. Although there is no theoretical upper limit on the thickness of the glass substrate 102, a thickness beyond that needed for the support function or that desired for the ultimate SiOG structure 100 might not be advantageous since the greater the thickness of the glass substrate 102, the more difficult it will be to accomplish at least some of the process steps in forming the SiOG structure 100.

The oxide glass or oxide glass-ceramic substrate 102 may be silica-based. Thus, the mole percent of SiO₂ in the oxide glass or oxide glass-ceramic may be greater than 30 mole % and may be greater than 40 mole %. In the case of glass-ceramics, the crystalline phase can be mullite, cordierite, anorthite, spinel, or other crystalline phases known in the art for glass-ceramics. Non-silica-based glasses and glass-ceramics may be used in the practice of one or more embodiments of the invention, but are generally less advantageous because of their higher cost and/or inferior performance characteristics. Similarly, for some applications, e.g., for SOI structures employing semiconductor materials that are not silicon-based, glass substrates which are not oxide based, e.g., non-oxide glasses, may be desirable, but are generally not advantageous because of their higher cost. As will be discussed in more detail below, in one or more embodiments, the glass or glass-ceramic substrate 102 is designed to match a coefficient of thermal expansion (CTE) of one or more semiconductor materials (e.g., silicon, germanium, etc.) of the layer 104 that are bonded thereto. The CTE match ensures desirable mechanical properties during heating cycles of the deposition process.

For certain applications, e.g., display applications, the glass or glass-ceramic 102 may be transparent in the visible, near UV, and/or IR wavelength ranges, e.g., the glass or glass ceramic 102 may be transparent in the 350 nm to 2 micron wavelength range.

Although the glass substrate 102 may be composed of a single glass or glass-ceramic layer, laminated structures can be used if desired. When laminated structures are used, the layer of the laminate closest to the semiconductor layer 104 may have the properties discussed herein for a glass substrate 102 composed of a single glass or glass-ceramic. Layers farther from the semiconductor layer 104 may also have those properties, but may have relaxed properties because they do not directly interact with the semiconductor layer 104. In the latter case, the glass substrate 102 is considered to have ended when the properties specified for a glass substrate 102 are no longer satisfied.

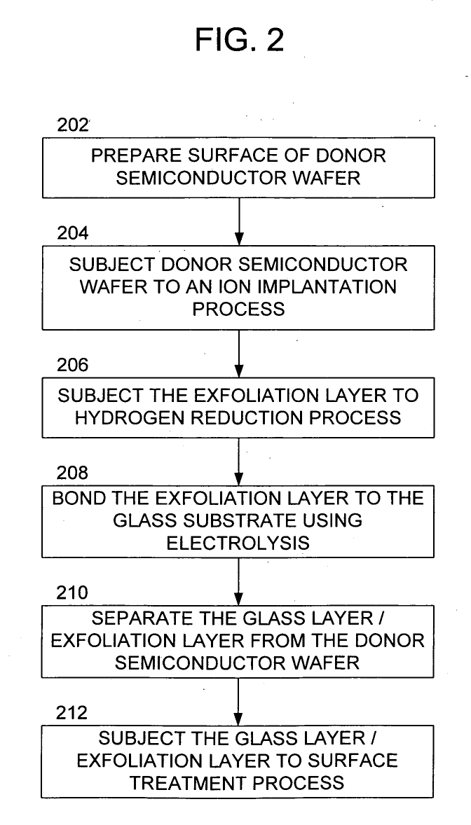

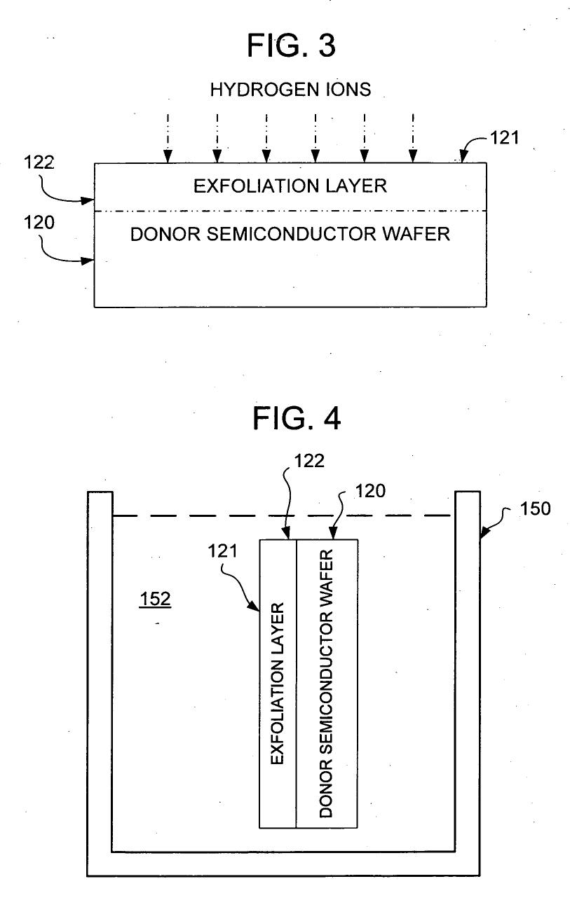

Reference is now made to FIGS. 2-7. FIG. 2 illustrates process steps that may be carried out in order to produce the SiOG structure 100 of FIG. 1 (and/or other embodiments disclosed herein), while FIGS. 3-7 illustrate intermediate structures and/or processes that may be achieved in carrying out the process of FIG. 2. Turning first to FIGS. 2 and 3, at action 202, an implantation surface 121 of a donor semiconductor wafer 120 is prepared, such as by polishing, cleaning, etc. to produce a relatively flat and uniform implantation surface 121 suitable for bonding to the glass or glass-ceramic substrate 102. For the purposes of discussion, the semiconductor wafer 120 may be a substantially single crystal Si wafer, although as discussed above any other suitable-semiconductor conductor material may be employed.

At action 204, an exfoliation layer 122 is created by subjecting the implantation surface 121 to one or more ion implantation processes to create a weakened region below the implantation surface 121 of the donor semiconductor wafer 120. Although the embodiments of the present invention are not limited to any particular method of forming the exfoliation layer 122, one suitable method dictates that the implantation surface 121 of the donor semiconductor wafer 120 may be subject to a hydrogen ion implantation process to at least initiate the creation of the exfoliation layer 122 in the donor semiconductor wafer 120. The implantation energy may be adjusted using conventional techniques to achieve a general thickness of the exfoliation layer 122, such as between about 300-500 nm. The implantation energy may be in the 100, KeV range. By way of example, hydrogen ion implantation may be employed, although other ions or multiples thereof may be employed, such as boron+hydrogen, helium+hydrogen, or other ions known in the literature for exfoliation. Again, any other known or hereinafter developed technique suitable for forming the exfoliation layer 122 may be employed without departing from the spirit and scope of the present invention.

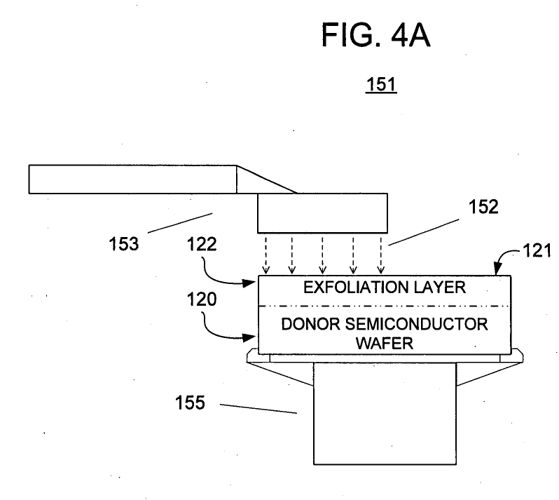

With reference to FIGS. 2 and 4, at action 206 the donor semiconductor wafer 120 may be treated to reduce, for example, the hydrogen ion concentration on the implantation surface 121. In accordance with one or more embodiments of the present invention, the process of reducing the concentration of hydrogen includes using ozonated water. While the embodiments the invention are not intended to be limited by any theory of operation, it is believed that the ozonated water at least partially causes hydrogen groups that have terminated at the implantation surface 121 to oxidize to hydroxyl groups. With reference to FIG. 4, the treatment of the donor semiconductor wafer 120, and the implantation surface 121 in particular, may be carried out in a bath 150, which may be temperature controlled. The bath 150 may include a solution 152 into which the SOI intermediate structure 122, 102 is disposed, where the solution 152 includes the aforementioned ozonated water.

With reference to FIG. 4A, the solution 152 may also be applied to the implantation surface 121 SOI intermediate structure 122, 102 via a spin/spray tool 151. The spin/spray tool 151 includes a sweeping spray arm 153 having a head that dispenses (e.g., sprays) the implantation surface 121 with the solution 152. The spin/spray tool 151 may include a rotating spindle 155 that rotates the intermediate structure 122, 102 under the head of the sweeping spray arm 153 such that the solution 152 may be evenly applied to the implantation surface 121.

The treatment may include subjecting the implantation surface 121 to agitation of the solution 152. For example, the bath 150 may be equipped such that the agitation may include stirring the solution, such as by magnetic stirring. Alternatively or in addition, the bath 150 may be equipped such that the agitation may include ultrasonic and/or megasonic wave propagation within the solution 152. It is understood that other techniques may be employed to apply the ozonated water to the implantation surface 121, such as by using a spin/spray tool application of the solution 152.

In accordance with one or more embodiments of the present invention the concentration and application (and/or agitation) time may be adjusted to achieve particular reductions in the concentration of hydrogen groups on the implantation surface 121. For example, the ozonated water may be at a concentration of about 5 ppm or greater of ozone in the solution 152. Additionally or alternatively, application of the solution 152 (with ozonated water) to the implantation surface 121 may be carried out for up to about 10 minutes.

In accordance with one or more embodiments of the present invention, the process of reducing the concentration of hydrogen may include washing the implantation surface 121 in a first solution and then rinsing the implantation surface in the ozonated water. In this regard, the solution 152 may be applied as the first solution (prior to application of ozonated water) and then changed to the solution 152 of ozonated water. The bath 150 may be used to apply a first solution 152 to the implantation surface 121 (although the bath 150 is not required as other application techniques may be employed).

In accordance with one or more embodiments of the present invention, the first solution 152 may include at least one of ammonia, hydrogen peroxide, and water. The number and concentration of these elements of the first solution 152 may be adjusted to achieve a particular result. By way of example, the first solution 152 may include about one part ammonia, about two to four parts hydrogen peroxide, and about twenty to thirty parts water. In addition, the temperature and time of application of the first solution 152 may be adjusted. For example, the first solution 152 may be applied at a temperature of about 20-70° C. Additionally or alternatively, application of the first solution 152 may be carried out for up to about 10 minutes. Further, the application of the first solution 152 may be carried out using any of the aforementioned agitation techniques, such as megasonic or ultrasonic agitation.

In accordance with one or more embodiments of the present invention, the process of reducing the concentration of hydrogen may include washing the implantation surface 121 in the first solution, applying a second solution, and then rinsing the implantation surface in the ozonated water. In this regard, the solution 152 may be applied as the first solution (prior to application of ozonated water), then changed to the second solution, and then changed again to the ozonated water. Again, the bath 150 may be used to apply the solutions 152 to the implantation surface 121 (although other application techniques may be employed additionally or in the alternative).

In accordance with one or more embodiments of the present invention, the second solution 152 may include at least one of hydrofluoric acid, hydrochloric acid, and water. The number and concentration of these elements of the second solution 152 may be adjusted to achieve a particular result. By way of example, the second solution 152 may include about one part hydrofluoric acid, one part hydrochloric acid, and up to about 200 parts water. In addition, the temperature and time of application of the second solution 152 may be adjusted. For example, the second solution 152 may be applied at a temperature of about 20 to 70° C. Additionally or alternatively, application of the second solution 152 may be carried out for up to about 5 minutes. Further, the application of the second solution 152 may be carried out using any of the aforementioned agitation techniques.

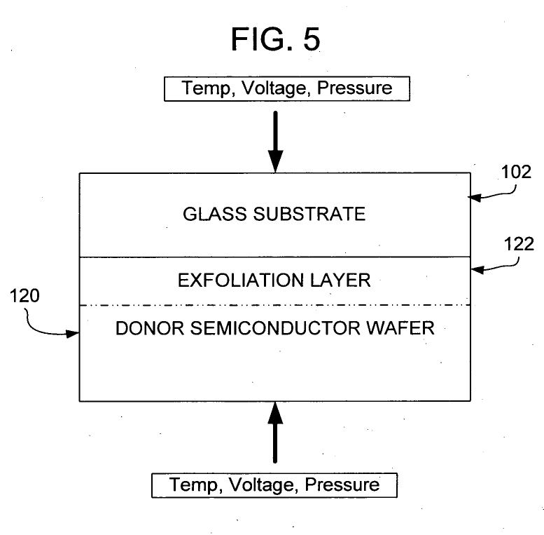

With reference to FIGS. 2 and 5, at action 208 the glass substrate 102 may be bonded to the exfoliation layer 122 using an electrolysis process. A suitable electrolysis bonding process is described in U.S. Patent Application No. 2004/0229444, the entire disclosure of which is hereby incorporated by reference. Portions of this process are discussed below. In the bonding process, appropriate surface cleaning of the glass substrate 102 (and the exfoliation layer 122 if not done already) may be carried out. Thereafter, the intermediate structures are brought into direct or indirect contact to achieve the arrangement schematically illustrated in FIG. 5. Prior to or after the contact, the structure(s) comprising the donor semiconductor wafer 120, the exfoliation layer 122, and the glass substrate 102 are heated under a differential temperature gradient. The glass substrate 102 may be heated to a higher temperature than the donor semiconductor wafer 120 and exfoliation layer 122. By way of example, the temperature difference between the glass substrate 102 and the donor semiconductor wafer 120 (and the exfoliation later 122) is at least 1 degree C., although the difference may be as high as about 100 to about 150 degrees C. This temperature differential is desirable for a glass having a coefficient of thermal expansion (CTE) matched to that of the donor semiconductor wafer 120 (such as matched to the CTE of silicon) since it facilitates later separation of the exfoliation layer 122 from the semiconductor wafer 120 due to thermal stresses.

Once the temperature differential between the glass substrate 102 and the donor semiconductor wafer 120 is stabilized, mechanical pressure is applied to the intermediate assembly. The pressure range may be between about 1 to about 50 psi. Application of higher pressures, e.g., pressures above 100 psi, might cause breakage of the glass substrate 102.

The glass substrate 102 and the donor semiconductor wafer 120 may be taken to a temperature within about +/−150 degrees C. of the strain point of the glass substrate 102.

Next, a voltage is applied across the intermediate assembly, for example with the donor semiconductor wafer 120 at the positive electrode and the glass substrate 102 the negative electrode. The application of the voltage potential causes alkali or alkaline earth ions in the glass substrate 102 to move away from the semiconductor/glass interface further into the glass substrate 102. This accomplishes two functions: (i) an alkali or alkaline earth ion free interface is created; and (ii) the glass substrate 102 becomes very reactive and bonds strongly to the exfoliation layer 122 of the donor semiconductor wafer 120 with the application of heat at relatively low temperatures.

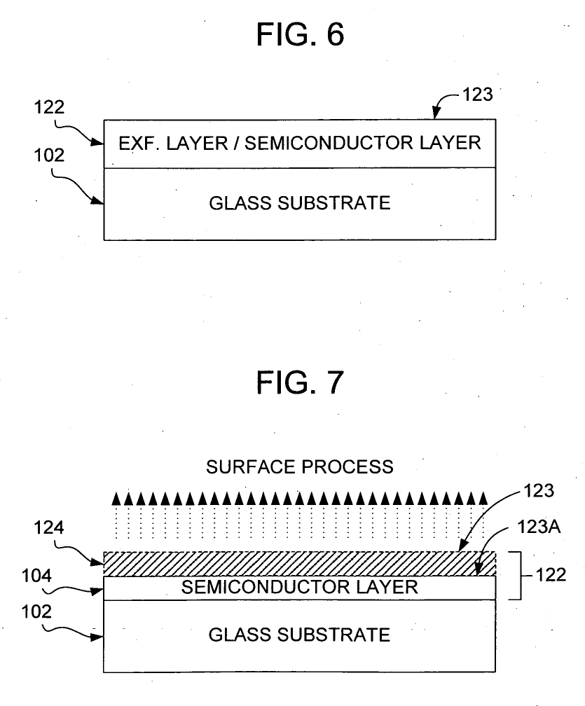

With reference to FIGS. 2 and 6, at action 210 after the intermediate assembly is held under the above conditions for some time (e.g., approximately 1 hour or less), the voltage is removed and the intermediate assembly is allowed to cool to room temperature. The donor semiconductor wafer 120 and the glass substrate 102 are then separated, which may include some peeling if they have not already become completely free, to obtain a glass substrate 102 with the relatively thin exfoliation layer 122 formed of the semiconductor material of the donor semiconductor layer 120 bonded thereto. The separation may be accomplished via fracture of the exfoliation layer 122 due to thermal stresses. Alternatively or in addition, mechanical stresses such as water jet cutting or chemical etching may be used to facilitate the separation.

As illustrated in FIG. 6, after separation the resulting structure may include the glass substrate 102 and the exfoliation layer 122 of semiconductor material bonded thereto. The cleared surface 123 of the SOI structure just after exfoliation may exhibit excessive surface roughness, excessive silicon layer thickness, and implantation damage of the silicon layer (e.g., due to the formation of an amorphized silicon layer). In some cases, the amorphized silicon layer may be on the order of about 50-150 nm in thickness. In addition, depending on the implantation energy and implantation time, the thickness of the exfoliation layer 122 may be on the order of about 300-500 nm. It is assumed for the purposes of discussion that the final thickness of the semiconductor layer 104 should be lower than 1 micron, for example, less than about 500 nm, such as 300 nm or lower.

Accordingly, with reference to FIGS. 2 and 7, action 212, the cleaved surface 123 is subject to surface treatment processing, which may include subjecting the cleaved surface 123 to a thinning process. Additionally or alternatively, the surface treatment processing may include subjecting the surface 123 (which may have been thinned to surface 123A) of the semiconductor layer 104 to polishing. The intent of the polishing step is to remove additional material from the semiconductor layer 104 by polishing the surface 123A down to a polished surface. The polishing step may include using polishing (or buffing) equipment to buff the etched surface 123 (or 123A) using silica based or ceria based slurries or similar material known in the art in the semiconductor industry. The polishing pressure may be between about 1 and 100 psi, the polishing platen speed may be between about 25-1000 rpm. This polishing process may be a deterministic polishing technique as known in the art.

In accordance with one or more further embodiments of the present invention, the resulting surface 123A may be subjected to one or more further cleaning processes following the aforementioned thinning and/or polishing treatments. The further cleaning processes may be similar to those performed on the intermediate structure 122, 102 as discussed above with reference to FIGS. 4 and 4A. Specifically, the processes may involve alternating applications of one or more of the first solution, the second solution and the solution containing ozonated water.

### EXAMPLE 1

An experiment was conducted to demonstrate the applicability of the aforementioned hydrogen reducing process on an SiOG structure. A donor semiconductor wafer, a silicon wafer, of 150 mm diameter and 500 microns thick was hydrogen ion implanted at dosage of 8×10¹⁶ ions/cm² and an implantation energy of 100 KeV. The donor semiconductor wafer was then washed in an automated washer (Akrion) in accordance with the following process: (i) washing the donor semiconductor wafer with a so-called SCl solution (which includes NH₄OH,H₂O₂,H₂O at concentrations of 1 part, 2 parts, and 20 parts, respectively) at a temperature of 60° C. for 10 minutes and at 1000 W megasonic agitation; (ii) applying a mixture to the donor semiconductor wafer, where the mixture was hydrofluoric and hydrochloric acid at concentrations of 1 part, 1 part, and 200 parts, respectively) at a temperature of 23° C. for 5 min); and (iii) rinsing the donor semiconductor wafer with ozonated water (at a concentration of 10 ppm) for 10 minutes. Following the ozonated water treatment the donor semiconductor wafer was dried. A Corning Eagle™ glass wafer was then washed in the automated washer (Akrion) using, the above SCl solution followed by a DI water rinse and dried. The donor semiconductor wafer and the glass were then brought into contact with each other with the implanted silicon wafer side facing the glass wafer. The wafers brought into contact in such a fashion formed a physical (Van Der Waal's) bond with each other. The wafers were then placed in a bonder. The glass wafer was placed on the negative electrode and the silicon wafer was placed on the positive electrode. The two wafers were heated to 525° C. (silicon wafer) and 575° C. (glass wafer). A potential of 1750 volts was applied across the wafer surfaces for 20 minutes, and then the voltage was brought to zero. The wafers were cooled to room temperature. The wafers were separated easily and a uniform silicon film transfer from the donor semiconductor wafer to the glass wafer was obtained.

### EXAMPLE 2

The experiment described in EXAMPLE 1 was repeated on a spin/spray tool with equivalent results.

### EXAMPLE 3

A post-polish cleaning experiment was conducted using a spin/spray tool. After slurry removal, the polished substrate was subjected to treatment with ozonated water, the first solution, the second solution, and again with ozonated water. Significant reduction in ionic contamination was measured by ToF SIMS.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of forming a semiconductor on glass structure, comprising:
subjecting an implantation surface of a donor semiconductor wafer to an ion implantation process to create an exfoliation layer of the donor semiconductor wafer; and
reducing a concentration of hydrogen at least at the implantation surface of the donor semiconductor wafer using ozonated water.

2. The method of claim 1, wherein the step of reducing the concentration of hydrogen includes washing the implantation surface in a first solution and then rinsing the implantation surface in the ozonated water.

3. The method of claim 2, wherein the ozonated water is at a concentration of about 5 ppm or greater of ozone.

4. The method of claim 2, wherein the step of washing the implantation surface with ozonated water is carried out for up to about 10 minutes.

5. The method of claim 1, wherein the ozonated water at least partially causes hydrogen groups that have terminated at the implantation surface to oxidize to hydroxyl groups.

6. The method of claim 2, wherein the first solution includes at least one of hydrogen peroxide and ammonia, hydrogen peroxide, and water.

7. The method of claim 6, wherein the first solution includes about one part ammonia, about two to four parts hydrogen peroxide, and about twenty to thirty parts water.

8. The method of claim 2, wherein the first solution is at a temperature of about 20 to 70° C.

9. The method of claim 2, wherein the step of washing the implantation surface in the first solution is carried out for up to about 10 minutes.

10. The method of claim 2, wherein the step of washing the implantation surface in the first solution is carried out using megasonic or ultrasonic agitation.

11. The method of claim 1, wherein the step of reducing the concentration of hydrogen includes washing the implantation surface in a first solution, then washing the implantation surface in a second solution, and then rinsing the implantation surface in the ozonated water.

12. The method of claim 11, wherein the second solution includes at least one of hydrofluoric acid, hydrochloric acid, and water.

13. The method of claim 12, wherein the second solution includes about one part hydrofluoric acid, one part hydrochloric acid, and 200 parts water.

14. The method of claim 11, wherein the second solution is at a temperature of about 23° C.

15. The method of claim 11, wherein the step of washing the implantation surface in the first solution is carried out for about 5 minutes.

16. The method of claim 1, wherein the step of reducing the concentration of hydrogen includes subjecting at least the implantation surface to agitation of at least one of the first solution and the ozonated water.

17. The method of claim 16, wherein the agitation includes at least one of stirring the solution, magnetic stirring of the solution, ultrasonic wave propagation within the solution, megasonic wave propagation within the solution, and spray application of the solution.

18. The method of claim 1, further comprising:
bonding the implantation surface of the exfoliation layer to a glass substrate using electrolysis; and
separating the exfoliation layer from the donor semiconductor wafer, thereby exposing at least one cleaved surface.

19. The method of claim 18, wherein the step of bonding includes:
heating at least one of the glass substrate and the semiconductor wafer;
bringing the glass substrate into direct or indirect contact with the semiconductor wafer through the exfoliation layer; and
applying a voltage potential across the glass substrate and the semiconductor wafer to induce the bond.

20. The method of claim 19, wherein the temperature of the glass substrate and the semiconductor wafer are elevated to within about 150 degrees C. of the strain point of the glass substrate.

21. The method of claim 19, wherein the temperatures of the glass substrate and the semiconductor wafer are elevated to different levels.

22. The method of claim 19, wherein the voltage potential across the glass substrate and the semiconductor wafer is between about 100 to 2000 volts.

23. The method of claim 1, wherein the donor semiconductor wafer is taken from the group consisting of:
silicon (Si), germanium-doped silicon (SiGe), silicon carbide (SiC), germanium (Ge), gallium arsenide (GaAs), GaP, and InP.

24. A method of forming a semiconductor on glass structure, comprising:
subjecting an implantation surface of a donor semiconductor wafer to an ion implantation process to create an exfoliation layer of the donor semiconductor wafer;
bonding the implantation surface of the exfoliation layer to a glass substrate using electrolysis; and
separating the exfoliation layer from the donor semiconductor wafer, thereby exposing at least one cleaved surface;
subjecting the cleaved surface to thinning or polishing to produce a post processed surface; and
subjecting the post processed surface to a cleaning process using ozonated water.

25. The method of claim 24, wherein the cleaning process includes washing the post processed surface in a first solution and then rinsing the implantation surface in the ozonated water.

26. The method of claim 24, wherein at least one of:
the ozonated water is at a concentration of about 5 ppm or greater of ozone;
the step of washing the post processed surface with ozonated water is carried out for up to about 10 minutes;
the ozonated water at least partially causes hydrogen groups that have terminated at the post processed surface to oxidize to hydroxyl groups;
the first solution includes at least one of hydrogen peroxide and ammonia, hydrogen peroxide, and water.

27. The method of claim 26, wherein at least one of:
the first solution includes about one part ammonia, about two to four parts hydrogen peroxide, and about twenty to thirty parts water;
the first solution is at a temperature of about 20 to 70° C.;
the cleaning the post processed surface using the first solution is carried out for up to about 10 minutes; and
the step of the cleaning the post processed surface using the first solution is carried out using megasonic or ultrasonic agitation.

28. The method of claim 24, wherein the step the cleaning the post processed surface includes washing the post processed surface in a first solution, then washing the post processed surface in a second solution, and then rinsing the post processed surface in the ozonated water.

29. The method of claim 28, wherein at least one of:
the second solution includes at least one of hydrofluoric acid, hydrochloric acid, and water; and
the second solution includes about one part hydrofluoric acid, one part hydrochloric acid, and 200 parts water.

30. The method of claim 28, wherein at least one of:
the second solution is at a temperature of about 23° C.; and
the step of washing the post processed surface in the first solution is carried out for about 5 minutes.

31. The method of claim 24, wherein at least one of:
the cleaning process includes subjecting at least the post processed surface to agitation of at least one of the first solution and the ozonated water; and
the agitation includes at least one of stirring the solution, magnetic stirring of the solution, ultrasonic wave propagation within the solution, megasonic wave propagation within the solution, and spray application of the solution.
